(19) United States
(12) Patent Application Publication
(10) Pub. No.: US 2026/0251730 A1
(43) Pub. Date: Aug. 27, 2026

(54) Method and Device for Detecting an Impairment of the Cell Contacting System of a Cell Unit of a Battery

(71) Applicant: Bayerische Motoren Werke Aktiengesellschaft, Muenchen (DE)

(72) Inventors: Le Bao Huy CHAU, Muenchen (DE); Eva STIEHL, Muenchen (DE)

(21) Appl. No.: 19/160,182

(22) PCT Filed: Mar. 1, 2024
(86) PCT No.: PCT/EP2024/055460

§ 371 Date: Aug. 27, 2025

(30) Foreign Application Priority Data
Mar. 24, 2023 (DE) 10 2023 107 407.5

(51) Int. Cl. G01R 31/66; G01R 31/367; G01R 31/374; G01R 31/392; H01M 10/42

(52) U.S. Cl. CPC G01R 31/66; G01R 31/367; G01R 31/374; G01R 31/392; H01M 10/4285

(57) ABSTRACT

The disclosure relates to a device for detecting an impairment of a cell contacting system of a cell unit of an electrical energy store. The device is configured to determine a temporal progression of the voltage at the cell unit during a charging process or a discharging process of the energy store and to detect an impairment of the cell contacting system of the cell unit based on the temporal progression of the voltage at the cell unit.

### BACKGROUND AND SUMMARY

The present disclosure relates to a device and a corresponding method, using which an impairment of the cell contacting system of a cell unit of an electrical battery cell can be detected in an efficient and reliable manner.

An at least partially electrically driven vehicle has an energy storage device for storing electrical energy for the operation of an electrical drive motor of the vehicle. The energy storage device typically comprises a plurality of individual storage cells, for example a plurality of round cells and/or pouch cells, which are arranged in a housing of the energy storage device. The storage cells can be grouped into cell units each having multiple individual storage cells. The storage cells within the individual cell units can each be electrically conductively connected to one another via a cell contacting system.

The cell contacting system of a cell unit of an electrical energy storage device can have an impairment, for example due to aging and/or due to a mechanical effect. The present document relates to a technical object of detecting an impairment of the cell contacting system of a cell unit of an electrical energy storage device in an efficient and reliable manner.

This object is achieved by aspects of the present disclosure. Advantageous embodiments are also described herein.

According to one aspect, a device for detecting an impairment of a cell contacting system of a cell unit of an electrical energy storage device is described. The energy storage device can have a rated voltage of 300 V or more. The energy storage device can be designed to provide electrical energy for the operation of an electrical drive machine of a (motor) vehicle.

The cell unit can comprise P storage cells electrically arranged in parallel, for example with P>1, in particular P=2, P=3, P=4, P=5, or more. The cell contacting system can be designed to electrically connect the P storage cells of the cell unit in parallel. An impairment of the cell contacting system can comprise, for example, faulty, in particular absent, electrical contacting of at least one storage cell of the cell unit.

The device is configured to determine a temporal progression of the voltage at the cell unit (i.e. between the two poles of the cell unit) during a charging procedure or a discharging procedure of the energy storage device. The voltage can be registered by a voltage measuring unit. The temporal progression can indicate how the voltage changes with time, in particular increases or reduces. The temporal progression can have, for example, 5 voltage values or more, or 10 voltage values or more, or 50 voltage values or more for correspondingly many different points in time.

The temporal progression of the voltage can have a gradient which specifies the change of the temporal progression as a function of a time unit (for example, per second or per minute). The gradient can depend on the level of the charging or discharging current of the charging or discharging procedure of the energy storage device.

The device is furthermore configured to detect an impairment of the cell contacting system of the cell unit based on the temporal progression, in particular based on the gradient of the temporal progression, of the voltage at the cell unit.

The device can furthermore be configured to effect a safety measure, in particular the output of a notification to a user of the energy storage device (in particular to the user of the vehicle in which the energy storage device is installed) when an impairment of the cell contacting system of the respective cell unit has been detected. Particularly safe operation of the energy storage device can thus be effected.

A device is therefore described which is designed to analyze the dynamic development of the voltage at at least one cell unit in order to detect an impairment of the cell contacting system of the cell unit in a particularly reliable manner.

The device can be configured to determine a reference progression of the voltage for the charging procedure or the discharging procedure. The reference progression can specify the expected progression of the voltage at the cell unit, for when no impairment of the contacting system of the cell unit exists.

The reference progression of the voltage can depend on a reference model for the cell unit, in particular on values of one or more model parameters of the reference model. The values of the one or more model parameters can describe the current state of the cell unit and/or the current charging procedure or discharging procedure. Exemplary model parameters are
configuration data with respect to the configuration of the cell unit, in particular with respect to the number P of storage cells arranged in parallel;
aging data with respect to the aging of the P storage cells of the cell unit (at the point in time of the charging procedure or the discharging procedure);
data with respect to the state of health of the P storage cells of the cell unit (at the point in time of the charging procedure or the discharging procedure);
temperature data with respect to the temperature of the cell unit (at the point in time of the charging procedure or the discharging procedure);
data with respect to the state of charge of the cell unit during, in particular at the beginning of, the charging procedure or the discharging procedure;
data with respect to the charging current or the discharging current (in particular the amperage) during the charging procedure or the discharging procedure; and/or
load data with respect to a current load (possibly cumulative over time) of the cell unit.

The impairment of the cell contacting system of the cell unit can also be detected in a particularly reliable manner based on the reference progression. In particular, the device can be configured to compare the ascertained temporal progression to the reference progression, and to detect the impairment of the cell contacting system of the cell unit based on the comparison.

The device can be configured in particular (in the context of the comparison) to determine the value of a deviation measure (for example, a mean square deviation) for the deviation of the determined temporal progression from the reference progression. It can be determined that an impairment of the cell contacting system of the cell unit exists if the value of the deviation measure is equal to or greater than a deviation threshold value. On the other hand, it can be determined that no impairment of the cell contacting system of the cell unit exists if the value of the deviation measure is less than the deviation threshold value.

An impairment of the cell contacting system can be detected in a particularly reliable manner by the comparison of the registered temporal progression with a reference progression.

As already described further above, the device can be configured to detect an impairment of the cell contacting system of the cell unit based on the gradient of the temporal progression of the voltage at the cell unit. The gradient of the temporal progression can be compared here with the reference gradient of the reference progression of the voltage in order to detect the impairment of the cell contacting system in a particularly reliable manner.

The device can be configured to determine, based on a reference model (determined beforehand) for the voltage at the cell unit, reference data, in particular the reference progression of the voltage and/or the reference gradient of the reference progression of the voltage, for the charging procedure or the discharging procedure. The reference model can comprise one or more model parameters. The device can be configured to determine values for the one or more model parameters of the reference model for the charging procedure or the discharging procedure. The reference data can then be determined using the determined values for the one or more model parameters of the reference model.

An impairment of the cell contacting system of the cell unit can be detected in a particularly reliable manner based on the reference data.

The device can be configured to determine the temporal progression of the voltage at the cell unit for each of a sequence of successive charging procedures and/or discharging procedures of the energy storage device (by the voltage measuring unit). It can then be checked based on the respectively determined temporal progression of the voltage at the cell unit whether or not an impairment of the cell contacting system of the cell unit exists. Safe operation of the energy storage device can thus be effected continuously.

The energy storage device typically comprises a plurality of cell units which can be electrically arranged in series. The device can be configured to determine a temporal progression of the voltage at the respective cell unit for each of the plurality of cell units for the charging procedure or the discharging procedure of the energy storage device (using a dedicated voltage measuring unit). It can then be checked based on the temporal progression of the voltage at the respective cell unit whether or not an impairment of the cell contacting system of the respective cell unit exists. Comprehensive monitoring of the cell units of the energy storage device can thus be effected in order to further increase the safety of the operation of the energy storage device.

According to a further aspect, a (road) motor vehicle (in particular a passenger vehicle or a truck or a bus or a motorcycle) is described, which comprises the device described in this document.

According to a further aspect, a method for detecting an impairment (in particular a contacting fault) of a cell contacting system of a cell unit of an electrical energy storage device (for example of a motor vehicle) is described. The cell unit can comprise P storage cells electrically arranged in parallel, with P>1.

The method comprises determining, during a charging procedure or a discharging procedure of the energy storage device, a temporal progression of the voltage at the cell unit. The method furthermore comprises detecting an impairment of the cell contacting system of the cell unit based on the temporal progression of the voltage at the cell unit.

According to a further aspect, a software (SW) program is described. The SW program can be configured to be executed on a processor (for example on a controller of a vehicle), and to thus carry out the method described in this document.

According to a further aspect, a storage medium is described. The storage medium can comprise an SW program, which is configured to be executed on a processor, and to thus carry out the method described in this document.

It is to be noted that the methods, devices, and systems described in this document can be used both alone and in combination with other methods, devices, and systems described in this document. Furthermore, any aspects of the methods, devices, and systems described in this document can be combined with one another in a variety of ways. In particular, the disclosed aspects can be combined with one another in a variety of ways. Furthermore, features set forth in parentheses are to be understood as optional features.

The disclosure will be described in more detail hereinafter based on exemplary embodiments.

### BRIEF DESCRIPTION OF THE DRAWINGS

FIG. 1 shows an exemplary vehicle having an energy storage device for storing electrical energy;

FIG. 2a shows an exemplary round cell;

FIG. 2b shows an exemplary electrical energy storage device having a plurality of round cells;

FIG. 2c shows exemplary cell units each having a cell contacting system;

FIG. 3a shows an exemplary measurement of the voltage at a cell unit;

FIG. 3b shows exemplary temporal progressions of the voltage at a cell unit; and

FIG. 4 shows a flow chart of an exemplary method for detecting an impairment of the cell contacting system of a cell unit of an electrical energy storage device.

### DETAILED DESCRIPTION OF THE DRAWINGS

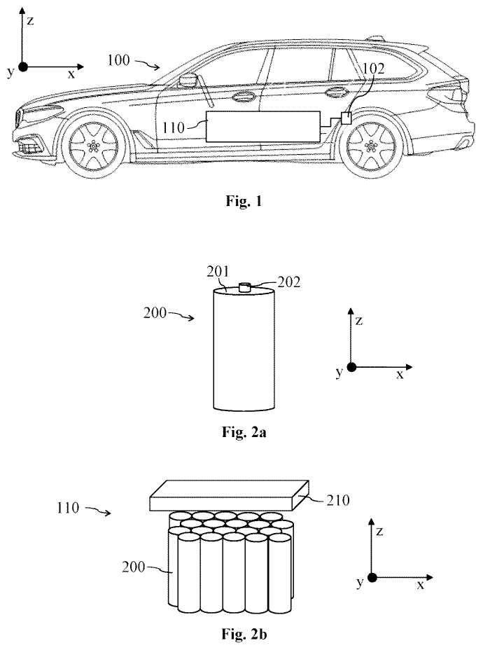

As described at the outset, the present document relates to the efficient and precise detection of an impairment of the cell contacting system of a cell unit of an electrical energy storage device. In this context, FIG. 1 shows an exemplary vehicle 100 having an electrical energy storage device 110 for storing electrical energy and an electrical drive motor 102, which is operated using electrical energy from the energy storage device 110. The energy storage device 110 is typically installed here inside a housing in the vehicle 100.

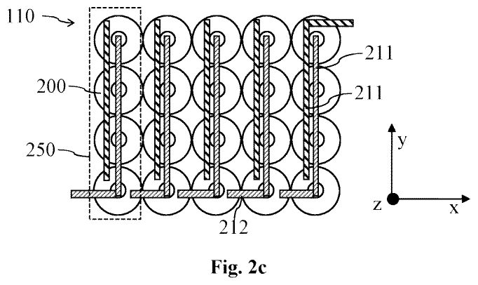

The energy storage device 110 typically comprises a plurality of storage cells, in particular round cells. FIG. 2a shows an exemplary storage cell 200, in particular a round cell, for an electrical energy storage device 110. The storage cell 200 has a circular-cylindrical shape. A positive contact point 201 and a negative contact point 202 for the electrical connection of the storage cell 200 are arranged on an end face of the storage cell 200. The positive contact point 201 can be formed here by the end face of the cylindrical storage cell 200. The negative contact point 202 can be formed by a pin, which protrudes from the end face of the storage cell 200. In a further example, the polarity of the contact points 201, 202 can be precisely reversed.

FIG. 2b shows an exemplary electrical energy storage device 110, which comprises a plurality of storage cells 200 that are arranged side by side (i.e. lateral surface at lateral surface) adjacent to one another, in particular such that the contact points 201, 202 of the individual storage cells 200 are arranged on a uniform side (in FIG. 2b on the top side). The energy storage device 110 can comprise, for example, 100 or more storage cells 200, or 1000 or more storage cells 200.

The individual storage cells 200 can be electrically conductively connected to one another via a cell contacting system 210. The cell contacting system 210 can comprise, for example, a frame having connecting lines or having connecting webs for electrically contacting the contact points 201, 202 of the individual storage cells 200. The cell contacting system 210 can be arranged on the side of the storage cells 200, on which the contact points 201, 202 of the storage cells 200 are also arranged.

The cell contacting system 210 of an energy storage device 110 can be designed to group the storage cells 200 into multiple different cell units, wherein the individual cell units each comprise P storage cells 200, which are arranged in parallel to one another, for example, P≥2. Furthermore, the individual cell units can be connected in series.

FIG. 2c illustrates an energy storage device 110, which comprises multiple cell units 250 each having P=4 storage cells 200. The cell contacting system 210 for the energy storage device 110 comprises individual cell contacting systems 211 for the individual cell unit 250, by which the storage cells 200 of the respective cell unit 250 are connected in parallel. Furthermore, the cell contacting system 210 for the energy storage device 110 comprises contacting elements 212, by which the individual cell units 250 are connected in series.

In the course of the service life of an energy storage device 110, an impairment of the cell contacting systems 211 of the individual cell units 250 of the energy storage device 110 can occur due to aging effects and/or due to mechanical effects. Measures are described in the present document, using which an impairment of a cell contacting system 211 of a cell unit 250 of an energy storage device 110 can be detected in an efficient and reliable manner.

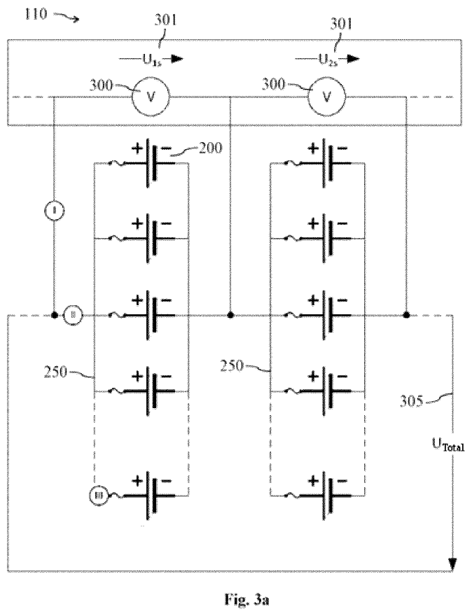

FIG. 3a illustrates an energy storage device 110 having multiple cell units 250 connected in series and each having P storage cells 200. The energy storage device 110 comprises measuring units 300 for the individual cell units 250. The measuring unit 300 for a cell unit 250 can be configured to register a measured value with respect to the electrical voltage 301 that is applied at the respective cell unit 250. The voltage 301 typically increases with increasing state of charge of the cell unit 250 and/or decreases with decreasing state of charge of the cell unit 250. Furthermore, the value of the total voltage 305 at the poles of the energy storage device 110 can be determined by a dedicated measuring unit.

During a charging procedure (and possibly in a corresponding manner during a discharging procedure), the temporal progression (of the measured values) of the voltage 301 at the cell unit 250 can be registered by the measuring unit 300 of a cell unit 250. FIG. 3b shows an exemplary measured (temporal) progression 322 of the voltage 301. The measured progression 322 extends from a first voltage value 311, for example a lower voltage limiting value (which corresponds, for example, to a first state of charge, such as 0%) up to a second voltage value 312, for example an upper voltage limiting value (which corresponds, for example, to a second state of charge, such as 100%). Furthermore, the measured progression 322 has a specific temporal gradient 324, wherein the temporal gradient 324 specifies the extent of the voltage change per unit of time (for example per second or per minute).

An impairment of the cell contacting system 211 of a cell unit 250 typically has the result that the contact resistance increases between at least one storage cell 200 of the cell unit 250 and the cell contacting system 211. As a result thereof, the effective resistance of the affected storage cell 200 increases, which has the result that the voltage 301 at the cell unit 250 increases faster (with uniform charging current). The accelerated increase of the voltage 301 has the result that the measured progression 322 has an increased temporal gradient 324. An impairment of the cell contacting system 211 of a cell unit 250 of an energy storage device 110 can therefore be detected in an efficient and reliable manner based on the temporal progression 322 of the voltage 301, in particular based on the gradient 324 of the temporal progression 322 of the voltage 301.

FIG. 3b shows a temporal reference progression 321 of the voltage 301 for a cell unit 250 having a non-impaired cell contacting system 211. The reference progression 321 can have been determined specifically for the respective cell unit 250 and/or for the respective charging or discharging procedure. The reference progression 321 has a temporal reference gradient 323. The measured progression 322 can be compared with the reference progression 321; in particular, the measured gradient 324 can be compared with the reference gradient 323 in order to detect an impairment of the cell contacting system 211 of the cell unit 250 in a particularly reliable manner.

As described at the outset, mechanical damage to the cell contacting system 210, 211, 212 can occur in operation of a high-voltage battery 110. This damage can be detected early by the measures described in this document, in order to enable particularly safe operation of the battery 110.

The electrical voltages 301 of individual cells 200 and/or individual cell units 250 of a battery 110 can be monitored in order to ensure that one or more safety limits 311, 312 of the respective cell 200 or cell unit 250 are not infringed. For example, excessively deep discharging and/or excessively wide charging can be prevented.

In this document, a dynamic evaluation of the voltage 301 at a cell unit 250 is described in order to detect an impairment of the cell contacting system 210, 211. In particular, a conclusion about damage in the battery 110 (for example, an interrupted line) can be drawn by the dynamic evaluation of the cell voltage data 322 during the operation of a battery 110. A safety measure can thus be initiated early, for example outputting an error message or warning to the user of the vehicle 100 in which the battery 110 is installed.

The electrical voltages 301 of the individual logical cells (i.e. the individual cell units) 250 in a battery 110 can be dynamically monitored by a software function in order to detect damage. In the battery 110, multiple cells 200 are typically electrically connected in parallel in individual cell units 250 which are in turn electrically connected in series, in order to provide the required system voltages and operating currents for the operation of the electrical drive machine 102 of a vehicle 100. A logical cell 250 can be a network, in particular a p-network, of multiple parallel individual cells 200. This form of interconnection of the individual cells 200 is ensured by the cell contacting system (CCS) 210, 211.

The voltages 301 of the individual logical cells 301 and the total voltage 305 of the battery 110 can be registered and evaluated by an internal voltage monitoring function 300. Multiple fault cases are conceivable, which relate to mechanical damage to the CCS 210, 211 and the interruption of one or more electrical lines (see FIG. 3a). For example, a sensor line to a voltage measuring unit 300 can be defective (see I in FIG. 3a). Such a fault can be detected in that the voltage values of the corresponding cell unit 250 are absent, but, on the other hand, the total voltage 305 of the battery 110 can be measured.

For II in FIG. 3a, a defect can be present in the main current path, which under load possibly also results in a defect in the one or more sensor lines. Such a fault can be detected since the voltage values of the individual cell units 250 are absent and since the total voltage 305 cannot be correctly registered.

In the event of a line interruption within a p-network, i.e. within a cell unit 250, the voltage values 301 of the cell unit 250 and total voltage 305 are typically correct. Such a line interruption can be detected by the dynamic analysis, described in this document, of the voltages 301 of the individual logical cells 250 in operation.

In the context of the dynamic analysis, a statistical evaluation of the voltage values 301 (for example deviations of the min/max values from the mean value) can be carried out. Furthermore, the gradients 324 of the voltage change during the charging or discharging can be analyzed.

If individual cells 200 drop out in a p-network 250, a reduced capacity of the resulting logical cell 250 results. Since the remaining, still contacted cells 200 are now loaded more strongly, the voltage progression 322 during the charging or discharging changes. In particular, the logical cell 250 is fully charged faster or discharged faster.

A digital twin (i.e. a reference model) of the cell voltages 301 can be determined and provided. Based on data from the assembly and/or the configuration of the battery 110, a model of the battery 110 can be prepared and provided with initial values of the cell voltages 301. Further aspects such as state of health of the cells 200, state of charge, and/or current load over the usage duration of the battery 110 can be incorporated into the model. If the behavior predicted by the model deviates (in particular suddenly) from the measured value of the battery 110, a defect can be concluded therefrom. The defect can be detected, for example, based on a change of the internal resistance of a logical cell 250 or based on a deviation in the course 322 of the cell voltage 310. The calculations for the model over the running time can take place in a (vehicle-external) cloud and/or in the vehicle 100.

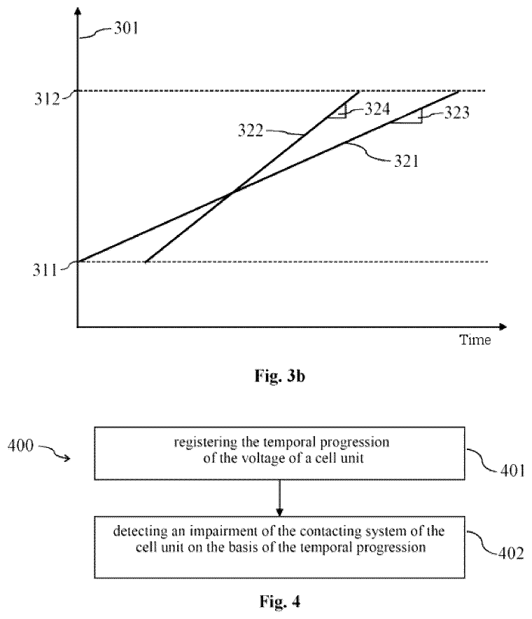

FIG. 4 shows a flow chart of an exemplary (possibly computer-implemented) method 400 for detecting an impairment of the cell contacting system 211 of a cell unit 250 of an electrical energy storage device 110. The cell unit 250 can comprise P storage cells 200 electrically arranged in parallel, with P>1.

The method 400 comprises determining 401, during a charging procedure or a discharging procedure of the energy storage device 110, the temporal progression 322 of the voltage 301 at the cell unit 250 (for example using a voltage measuring unit 300). The temporal progression 322 can specify the voltage 301 at the cell unit 250 as a function of time (for example for 10 or more, or 50 or more successive points in time).

Furthermore, the method 400 comprises detecting 402 an impairment of the cell contacting system 211 of the cell unit 250 based on the temporal progression 322 (in particular based on the gradient 324) of the voltage 301 at the cell unit 250. A reference progression 321 of the voltage 301 can be determined and/or taken into consideration here for the charging procedure or the discharging procedure, wherein the reference progression 321 depends, for example, on the charging current or the discharging current. The reference progression 321, in particular the reference gradient 323 of the reference progression 321, can be taken into consideration in the detection of an impairment of the cell contacting system 211.

An impairment of the cell contacting system of a cell unit 250 of an electrical energy storage device 119 can be detected in an efficient and precise manner by the measures described in this document.

The present disclosure is not restricted to the exemplary embodiments shown. In particular, it is to be noted that the description and the figures are only to illustrate the principle of the proposed methods, devices, and systems by way of example.

1-11. (canceled)

12. A device for detecting an impairment of a cell contacting system of a cell unit of an electrical energy storage device, comprising:
a processor; and
a non-transitory storage medium comprising a software program that, when executed by the processor, is configured to cause the processor to:
during a charging procedure or a discharging procedure of the energy storage device, determine a temporal progression of a voltage at the cell unit; and
detect an impairment of the cell contacting system of the cell unit based on the temporal progression of the voltage at the cell unit,
wherein the cell unit comprises P storage cells electrically arranged in parallel, with P>1.

13. The device according to claim 12, wherein the software program is further configured to cause the processor to:
determine a reference progression of the voltage for the charging procedure or the discharging procedure, wherein the reference progression specifies an expected progression of the voltage at the cell unit when no impairment of the contacting system of the cell unit exists; and
detect the impairment of the cell contacting system of the cell unit based on the reference progression.

14. The device according to claim 13, wherein the software program is further configured to cause the processor to:
compare the determined temporal progression to the reference progression; and
detect the impairment of the cell contacting system of the cell unit based on the comparing the determined temporal progression to the reference progression, wherein:
an impairment of the cell contacting system of the cell unit is detected based on a value of a deviation measure for a deviation of the determined temporal progression from the reference progression is equal to or greater than a deviation threshold value; and/or
it is detected that no impairment of the cell contacting system of the cell unit exists based on the value of the deviation measure is less than the deviation threshold value.

15. The device according to claim 12, wherein the software program is further configured to cause the processor to detect the impairment of the cell contacting system of the cell unit based on a comparison of a gradient with a reference gradient of a reference progression of the voltage.

16. The device according to claim 12, wherein the software program is further configured to cause the processor to:
determine a reference model for the voltage at the cell unit;
determine values for one or more model parameters of the reference model for the charging procedure or the discharging procedure;
based on the reference model using the determined values for the one or more model parameters, determine reference data for the charging procedure or the discharging procedure, the reference data comprising a reference progression of the voltage and/or a reference gradient of the reference progression of the voltage; and
detect the impairment of the cell contacting system of the cell unit based on the reference data.

17. The device according to claim 16, wherein the one or more model parameters comprises:
configuration data corresponding to a configuration of the cell unit with respect to the P of storage cells arranged in parallel;
aging data with respect to aging of the P storage cells;
state of health data corresponding to a state of health of the P storage cells;
temperature data corresponding to a temperature of the cell unit;
state of charge data corresponding to a state of charge of the cell unit during the charging procedure or the discharging procedure;
respective charging or discharging data corresponding to the charging current or the discharging current during the charging procedure or the discharging procedure; and/or
load data corresponding to a current load of the cell unit.

18. The device according to claim 12, wherein the software program is further configured to cause the processor to, for each of a sequence of successive charging procedures and/or discharging procedures of the energy storage device:
determine a temporal progression of the voltage at the cell unit; and
check, based on the temporal progression of the voltage at the cell unit, whether or not an impairment of the cell contacting system of the cell unit exists.

19. The device according to claim 12, wherein:
the energy storage device comprises a plurality of cell units electrically arranged in series; and
the software program is further configured to cause the processor to, for each of the plurality of cell units in each case for a charging procedure or a discharging procedure of the energy storage device:
determine a temporal progression of the voltage at the respective cell unit; and
check, based on the temporal progression of the voltage at the respective cell unit, whether or not an impairment of the cell contacting system of the respective cell unit exists.

20. The device according to claim 12, wherein the cell contacting system is configured to electrically connect the P storage cells of the cell unit in parallel.

21. The device according to claim 12, wherein the software program is further configured to cause the processor to: effect a safety measure comprising an output of a notification to a user of the energy storage device based on an impairment of the cell contacting system of the respective cell unit being detected.

22. A method for detecting an impairment of a cell contacting system of a cell unit of an electrical energy storage device; wherein the cell unit comprises P storage cells electrically arranged in parallel, with P>1; wherein the method comprises:
determining, during a charging procedure or a discharging procedure of the energy storage device, a temporal progression of a voltage at the cell unit; and
detecting an impairment of the cell contacting system of the cell unit based on the temporal progression of the voltage at the cell unit.

23. The method according to claim 22, further comprising:
determining a reference progression of the voltage for the charging procedure or the discharging procedure, wherein the reference progression specifies an expected progression of the voltage at the cell unit when no impairment of the contacting system of the cell unit exists; and
detecting the impairment of the cell contacting system of the cell unit based on the reference progression.

24. The method according to claim 23, further comprising:
comparing the determined temporal progression to the reference progression; and
detecting the impairment of the cell contacting system of the cell unit based on the comparing the determined temporal progression to the reference progression, wherein:
an impairment of the cell contacting system of the cell unit is detected based on a value of a deviation measure for a deviation of the determined temporal progression from the reference progression is equal to or greater than a deviation threshold value; and/or
it is detected that no impairment of the cell contacting system of the cell unit exists based on the value of the deviation measure is less than the deviation threshold value.

25. The method according to claim 22, further comprising detecting the impairment of the cell contacting system of the cell unit based on a comparison of a gradient with a reference gradient of a reference progression of the voltage.

26. The method according to claim 22, further comprising:
determining a reference model for the voltage at the cell unit;
determining values for one or more model parameters of the reference model for the charging procedure or the discharging procedure;
based on the reference model using the determined values for the one or more model parameters, determining reference data for the charging procedure or the discharging procedure, the reference data comprising a reference progression of the voltage and/or a reference gradient of the reference progression of the voltage; and
detecting the impairment of the cell contacting system of the cell unit based on the reference data.

27. The method according to claim 26, wherein the one or more model parameters comprises:
configuration data corresponding to a configuration of the cell unit with respect to the P of storage cells arranged in parallel;
aging data with respect to aging of the P storage cells;
state of health data corresponding to a state of health of the P storage cells;
temperature data corresponding to a temperature of the cell unit;
state of charge data corresponding to a state of charge of the cell unit during the charging procedure or the discharging procedure;
respective charging or discharging data corresponding to the charging current or the discharging current during the charging procedure or the discharging procedure; and/or
load data corresponding to a current load of the cell unit.

28. The method according to claim 22, further comprising, for each of a sequence of successive charging procedures and/or discharging procedures of the energy storage device:
determining a temporal progression of the voltage at the cell unit; and
checking, based on the temporal progression of the voltage at the cell unit, whether or not an impairment of the cell contacting system of the cell unit exists.

29. The method according to claim 22, wherein:
the energy storage device comprises a plurality of cell units electrically arranged in series; and
the method further comprises, for each of the plurality of cell units in each case for a charging procedure or a discharging procedure of the energy storage device:
determining a temporal progression of the voltage at the respective cell unit; and
checking, based on the temporal progression of the voltage at the respective cell unit, whether or not an impairment of the cell contacting system of the respective cell unit exists.

30. The method according to claim 22, further comprising:
effecting a safety measure comprising an output of a notification to a user of the energy storage device based on an impairment of the cell contacting system of the respective cell unit being detected.

31. A motor vehicle, comprising:
a device for detecting an impairment of a cell contacting system of a cell unit of an electrical energy storage device, comprising:
a processor; and
a non-transitory storage medium comprising a software program that, when executed by the processor, is configured to cause the processor to:
during a charging procedure or a discharging procedure of the energy storage device, determine a temporal progression of a voltage at the cell unit; and
detect an impairment of the cell contacting system of the cell unit based on the temporal progression of the voltage at the cell unit,
wherein the cell unit comprises P storage cells electrically arranged in parallel, with P>1.
